(19) United States
(12) Patent Application Publication
(10) Pub. No.: US 2012/0007674 A1
(43) Pub. Date: Jan. 12, 2012

(54) POWER AMPLIFIER REDUCING GAIN MISMATCH

(75) Inventors: Ki Yong SON, Daejeon (KR); Bon Hoon KOO, Daejeon (KR); Song Cheol HONG, Daejeon (KR); Gyu Suck KIM, Seoul (KR); Yoo Sam NA, Seoul (KR)

(73) Assignees: KOREA ADVANCED INSTITUTE OF SCIENCE AND TECHNOLOGY, Daejeon (KR); SAMSUNG ELECTRO-MECHANICS CO., LTD., Suwon (KR)

(21) Appl. No.: 13/020,273

(22) Filed: Feb. 3, 2011

(30) Foreign Application Priority Data
Jul. 6, 2010 (KR) 10-2010-0064976

(51) Int. Cl. H03F 3/45

(52) U.S. Cl. 330/253

(57) ABSTRACT

There is provided a power amplifier reducing a gain mismatch in order to reduce a gain mismatch between an N MOS amplifier and a P MOS amplifier by cross-connecting outputs from a two-stage amplification unit in a power amplifier having amplification units with a stacked structure in which the N MOS amplifier and the P MOS amplifier are connected in series with each other.

### CROSS-REFERENCE TO RELATED APPLICATIONS

This application claims the priority of Korean Patent Application No. 10-2010-0064976 filed on Jul. 6, 2010, in the Korean Intellectual Property Office, the disclosure of which is incorporated herein by reference.

### BACKGROUND OF THE INVENTION

1. Field of the Invention

The present invention relates to a power amplifier, and more particularly, to a power amplifier reducing a gain mismatch between an N MOS amplifier and a P MOS amplifier by cross-connecting outputs from a two-stage amplification unit in a power amplifier having amplification units with a stacked structure in which the N MOS amplifier and the P MOS amplifier are connected in series with each other.

2. Description of the Related Art

In general, a power amplifier, which is a large-signal circuit, experiences a breakdown with an increase in the amplitude of a signal.

In order to prevent this, a voltage swing between a gate and a drain of an active device and a voltage swing between a drain and a source thereof are limited. This limit may be determined by the level of a supply voltage and the kind of an active device.

In addition to a method of selecting a level of a supply voltage and a device, as described above, a cascode configuration and the like has been used in order to use a supply voltage having a higher level while using a given device. In such a cascode configuration, an N MOS amplifier has generally been used as an active device, which is connected in series between a supply voltage and a ground, so that a signal is output through a drain node of the N MOS amplifier.

Recently, the additional use of P MOS amplifiers, that is, a configuration having an N MOS amplifier and a P MOS amplifier being stacked e has been known in order to increase the level of the supply voltage.

However, a difference in gain between an N MOS amplifier and a P MOS amplifier may arise, due to the difference in characteristics thereof. For this reason, when respective output signals of the N MOS amplifier and the P MOS amplifier are coupled, signal distortion may occur.

### SUMMARY OF THE INVENTION

An aspect of the present invention provides a power amplifier reducing a gain mismatch between an N MOS amplifier and a P MOS amplifier by cross-connecting outputs between a two-stage amplification unit in a power amplifier having amplification units with a stacked structure in which the N MOS amplifier and the P MOS amplifier are connected in series with each other.

According to an aspect of the present invention, there is provided a power amplifier reducing a gain mismatch, the power amplifier including: a first amplification section including at least one first amplification unit having a first N MOS amplifier and a first P MOS amplifier stacked between a driving power terminal, through which a driving power having a predetermined voltage level is supplied, and a ground terminal; a first matching section performing impedance matching of respective output signals of the first N MOS amplifier and the first P MOS amplifier of the first amplification section; a second amplification section including at least one second amplification unit having a second N MOS amplifier and a second P MOS amplifier stacked between the driving power terminal and the ground terminal, inputting the output signal of the first N MOS amplifier of the first amplification section to the second P MOS amplifier and the output signal of the first P MOS amplifier of the first amplification section; and a power coupling section coupling output signals of the second N MOS amplifier and the second P MOS amplifier of the second amplification section.

The first N MOS amplifier may have a source connected to the driving power terminal, a gate receiving a negative input signal among balanced input signals being input, and a drain outputting an amplified signal, and the first P MOS amplifier may have a source connected to the ground terminal, a gate receiving a positive input signal among the balanced input signals being input, and a drain outputting an amplified signal and connected to the first N MOS amplifier through an inductor.

The first matching section may include: a first matching unit matching an impedance of a transmission path of the output signal through the drain of the first N MOS amplifier to a predetermined impedance and transmitting the output signal to the gate of the second P MOS amplifier of the second amplification section; and a second matching unit matching an impedance of a transmission path of the output signal through the drain of the first P MOS amplifier and transmitting the output signal to the gate of the second N MOS amplifier of the second amplification section.

The second N MOS amplifier may have a source connected to the driving power terminal, a gate receiving the output signal of the first P MOS amplifier from the second matching unit, and a drain outputting an amplified signal, and the second P MOS amplifier may have a source connected to the ground terminal, a gate receiving the output signal of the first N MOS amplifier from the first matching unit, and a drain outputting an amplified signal and connected to the drain of the second N MOS amplifier through an inductor.

The first amplification section may include a plurality of first amplification units, each of the plurality of first amplification units may have a first N MOS amplifier and a first P MOS amplifier stacked, the first N MOS amplifier may have a gate receiving a negative input signal among balanced input signals being input and a drain outputting an amplified signal, the first P MOS amplifier may have a gate receiving a positive input signal among the balanced input signals being input and a drain outputting an amplified signal and electrically connected to the drain of the first N MOS amplifier through an inductor, and the plurality of first amplification units are connected in series between the driving power terminal and the ground terminal.

The first matching section may include a plurality of matching units matching impedances of transmission paths of respective output signals being output through drains of the first N MOS amplifier and the first P MOS amplifier of each of the plurality of first amplification units.

The second amplification section may include a plurality of second amplification units respectively corresponding to the plurality of first amplification units of the first amplification section, each of the plurality of second amplification units may include a second N MOS amplifier and a second P MOS amplifier stacked, the second N MOS amplifier may have a gate receiving an output signal of a first P MOS amplifier of a corresponding first amplification unit among the plurality of first amplification units from one of the plurality of matching units, and a drain outputting an amplified signal, the second P MOS amplifier may have a gate receiving an output signal of a first N MOS amplifier of a corresponding first amplification unit among the plurality of first amplification units from one of the plurality of matching units, and a drain outputting an amplified signal and electrically connected to the drain of the second N MOS amplifier through an inductor, the plurality of second amplification units may be connected in series between the driving power terminal and the ground terminal, and the power coupling section may couple the output signals of the second N MOS amplifier and the second P MOS amplifier of each of the plurality of second amplification units.

The power amplifier may further include, between the second amplification section and the power coupling section: a third amplification section including at least one third amplification unit having a third N MOS amplifier and a third P MOS amplifier stacked between the driving power terminal and the ground terminal, and amplifying the output signals of the second amplification section; a second amplification section performing impedance matching of respective output signals from the third N MOS amplifier and the third P MOS amplifier of the third amplification section; and a fourth amplification section including at least one fourth amplification unit having a fourth N MOS amplifier and a fourth P MOS amplifier stacked between the driving power terminal and the ground terminal, inputting the output signal of the third N MOS amplifier of the third amplification section to the fourth P MOS amplifier, and inputting the output signal of the third P MOS amplifier of the third amplification section to the second N MOS amplifier, and the power coupling section couples output signals of the fourth N MOS amplifier and fourth P MOS amplifier of the fourth amplification section.

The third N MOS amplifier may have a source connected to the driving power terminal, a gate receiving the output signal of the second N MOS amplifier, and a drain outputting an amplified signal, the third P MOS amplifier may have a source connected to the ground terminal, a gate receiving the output signal of the second P MOS amplifier, and a drain outputting an output signal being amplified and connected to the drain of the third N MOS amplifier, the second amplification section may include a third matching unit matching an impedance of a transmission path of the output signal through the drain of the third N MOS amplifier to a predetermined impedance and transmitting the output signal to the gate of the fourth P MOS amplifier of the fourth amplification section, and a fourth matching unit matching an impedance of a transmission path of the output signal through the drain of the third P MOS amplifier to a predetermined impedance and transmitting the output signal to the gate of the fourth N MOS amplifier of the fourth amplification section, the fourth N MOS amplifier may have a source connected to the driving power terminal, a gate receiving the output signal of the third P MOS amplifier from the fourth matching unit, and a drain outputting an output signal being amplified, and the fourth P MOS amplifier may have a source connected to the ground terminal, a gate receiving the output signal of the third N MOS amplifier of the third matching unit, a drain outputting an output signal being amplified and connected to the drain of the fourth N MOS amplifier through an inductor.

The third N MOS amplifier may have a source connected to the driving power terminal, a gate receiving the output signal of the second P MOS amplifier, and a drain outputting an amplified signal, the third P MOS amplifier may have a source connected to the ground terminal, a gate receiving the output signal of the second N MOS amplifier, and a drain outputting an output signal being amplified and connected to the drain of the third N MOS amplifier through an inductor, the second amplification section may include a third matching unit matching an impedance of a transmission path of the output signal through the drain of the third N MOS amplifier to a predetermined impedance and transmitting the output signal to the gate of the fourth P MOS amplifier of the fourth amplification section, and a fourth matching unit matching an impedance of a transmission path of the output signal through the drain of the third P MOS amplifier to a predetermined impedance and transmitting the output signal to the gate of the fourth N MOS amplifier of the fourth amplification section, the fourth N MOS amplifier may have a source connected to the driving power terminal, a gate receiving the output signal of the third P MOS amplifier from the fourth matching unit, and a drain outputting an output signal being amplified, and the fourth P MOS amplifier may have a source connected to the ground terminal, a gate receiving the output signal of the third N MOS amplifier of the third matching unit, a drain outputting an output signal being amplified and connected to the drain of the fourth N MOS amplifier through an inductor.

The power amplifier may further include, between the second amplification section and the power coupling section, a third amplification section having a plurality of third amplification units respectively corresponding to the plurality of second amplification units of the second amplification section, the plurality of third amplification units each having a third N MOS amplifier and a third P MOS amplifier being stacked, the third N MOS amplifier having a gate receiving an output signal of a second P MOS amplifier of a corresponding second amplification unit among the plurality of second amplification units, and a drain outputting an amplified signal, the third P MOS amplifier having a gate receiving an output signal of a second N MOS amplifier of a corresponding second amplification unit among the plurality of second amplification units, and a drain amplifying an amplified signal and electrically connected to the drain of the third N MOS amplifier through an inductor, and the plurality of third amplification units connected in series between the driving power terminal and the ground terminal; a second matching section having a plurality of matching units matching impedances of transmission paths of respective output signals being output through the drain of the third N MOS amplifier and the drain of the third P MOS amplifier of each of the plurality of third amplification units; and a fourth amplification section having a plurality of fourth amplification units respectively corresponding to the plurality of third amplification units of the third amplification section, the plurality of fourth amplification units each having a fourth N MOS amplifier and a fourth P MOS amplifier being stacked, the fourth N MOS amplifier having a gate receiving an output signal of a third P MOS amplifier of a corresponding third amplification unit among the plurality of third amplification units from one matching unit of the plurality of matching units of the second matching section, and a drain outputting an amplified signal, the fourth P MOS amplifier having a gate receiving an output signal of a third N MOS amplifier of a corresponding third amplification unit among the plurality of third amplification units from one matching unit of the plurality of matching units of the second matching section, and a drain outputting an amplified signal and connected to the drain of the fourth N MOS amplifier through an inductor, and the plurality of fourth amplification units connected in series between the driving power terminal and the ground terminal, and the power coupling section couples the output signals of the fourth N MOS amplifier and the fourth P MOS amplifier of each of the plurality of fourth amplification units.

The power amplifier may further include, between the second amplification section and the power coupling section: a third amplification section having a plurality of third amplification units respectively corresponding to the plurality of second amplification units of the second amplification section, the plurality of third amplification units each having a third N MOS amplifier and a third P MOS amplifier being stacked, the third N MOS amplifier having a gate receiving an output signal of a second N MOS amplifier of a corresponding second amplification unit among the plurality of second amplification units, and a drain outputting an amplified signal, the third P MOS amplifier having a gate receiving an output signal of a second P MOS amplifier of a corresponding second amplification unit among the plurality of second amplification units, and a drain amplifying an amplified signal and electrically connected to the drain of the third N MOS amplifier through an inductor, and the plurality of third amplification units connected in series between the driving power terminal and the ground terminal; a second matching section having a plurality of matching units matching impedances of transmission paths of respective output signals being output through the drain of the third N MOS amplifier and the drain of the third P MOS amplifier of each of the plurality of third amplification units; and a fourth amplification section having a plurality of fourth amplification units respectively corresponding to the plurality of third amplification units of the third amplification section, the plurality of fourth amplification units each having a fourth N MOS amplifier and a fourth P MOS amplifier being stacked, the fourth N MOS amplifier having a gate receiving an output signal of a third P MOS amplifier of a corresponding third amplification unit among the plurality of third amplification units from one matching unit of the plurality of matching units of the second matching section, and a drain outputting an amplified signal, the fourth P MOS amplifier having a gate receiving an output signal of a third N MOS amplifier of a corresponding third amplification unit among the plurality of third amplification units from one matching unit of the plurality of matching units of the second matching section, and a drain outputting an amplified signal and connected to the drain of the fourth N MOS amplifier through an inductor, and the plurality of fourth amplification units connected in series between the driving power terminal and the ground terminal, and the power coupling section couples the output signals of the fourth N MOS amplifier and the fourth P MOS amplifier of each of the plurality of fourth amplification units.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating the configuration of a power amplifier according to an exemplary embodiment of the present invention;

FIG. 2 is a schematic view illustrating the configuration of a power amplifier according to another exemplary embodiment of the invention;

FIG. 3 is a schematic view illustrating the configuration of a power amplifier according to another exemplary embodiment of the invention;

FIG. 4 is a schematic view illustrating the configuration of a power amplifier according to another exemplary embodiment of the invention;

FIG. 5 is a schematic view illustrating the configuration of a power amplifier according to another exemplary embodiment of the invention;

FIG. 6 is a schematic view illustrating the configuration of a power amplifier according to another exemplary embodiment of the invention;

FIGS. 7A through 7D are graphs illustrating the electrical characteristics of an N MOS amplifier and a P MOS amplifier; and

FIGS. 8A and 8B are graphs illustrating the electrical characteristics of a power amplifier according to an exemplary embodiment of the present invention.

### DETAILED DESCRIPTION OF THE PREFERRED EMBODIMENT

Exemplary embodiments of the present invention will now be described in detail with reference to the accompanying drawings.

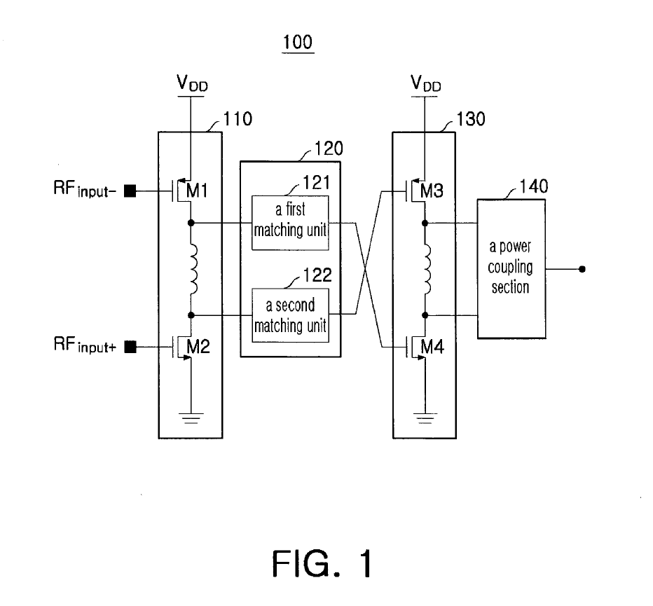

FIG. 1 is a schematic view illustrating the configuration of a power amplifier according to an exemplary embodiment of the invention.

Referring to FIG. 1, a power amplifier according to this embodiment may include a first amplification section 110, a first matching section 120, a second amplification section 130, and a power coupling section 140.

The first amplification section 110 may include at least one amplification unit. The at least one amplification unit may include a first N MOS (metal oxide semiconductor) amplifier M1 and a first P MOS amplifier M2 that are stacked between a driving power terminal VDD, through which a driving power having a predetermined voltage level is supplied, and a ground terminal.

That is, the first N MOS amplifier M1 may have a source that is electrically connected to the driving power terminal VDD, a gate that receives a negative input signal RFinput− among balanced input signals, and a drain that outputs an amplified signal.

In the same manner, the first P MOS amplifier M2 may have a source that is electrically connected to the ground terminal, a gate that receives a positive input signal RFinput+) among the balanced input signals, and a drain that outputs an amplified signal and is connected to the drain of the first N MOS amplifier M1 through an inductor. Here, there may be a difference in gain between the first N MOS amplifier M1 and the first P MOS amplifier M2 due to the respective individual characteristics thereof.

The first matching section 120 may include a first matching unit 121 and a second matching unit 122.

The first matching unit 121 matches the impedance of a transmission path of a signal, being output from the drain of the first N MOS amplifier M1, to a predetermined impedance.

In the same manner, the second matching unit 122 matches the impedance of a transmission path of a signal, being output from the drain of the first P MOS amplifier M2, to a predetermined impedance. Here, the first and second matching units 121 and 122 transmit the respective output signals to the second amplification section 130.

In the same manner, the second amplification section 130 may include at least one amplification unit. The at least one amplification unit may include a second N MOS amplifier M3 and a second P MOS amplifier M4 that are stacked between the driving power terminal VDD having a predetermined voltage level and the ground terminal.

That is, the second N MOS amplifier M3 may have a source that is electrically connected to the driving power terminal VDD, a gate that receives the output signal of the first P MOS amplifier M2 of the first amplification section 110, and a drain that outputs an amplified signal.

In the same manner, the second P MOS amplifier M4 may have a source that is electrically connected to the ground terminal, a gate that receives the output signal of the first N MOS amplifier M1 of the first amplification section 110, and a drain that outputs an amplified signal and is connected to the drain of the second N MOS amplifier M3.

As described above, the output signals of the first N MOS amplifier M1 and the first P MOS amplifier M2 of the first amplification section 110 are transmitted to the gates of the second P MOS amplifier M4 and the second N MOS amplifier M3 of the second amplification section 130, respectively, through the first matching section 120. That is, the output signal of the first N MOS amplifier M1 of the first amplification section 110 is transmitted to the gate of the second P MOS amplifier M4 of the second amplification section 130, while the output signal of the first P MOS amplifier M2 is transmitted to the gate of the second N MOS amplifier M3, thereby offsetting the difference in gain between the N MOS amplifier and the P MOS amplifier.

The power coupling section 140 may couple the signal, amplified by the second N MOS amplifier M3, and the signal, amplified by the second P MOS amplifier M4, to thereby output an unbalanced signal.

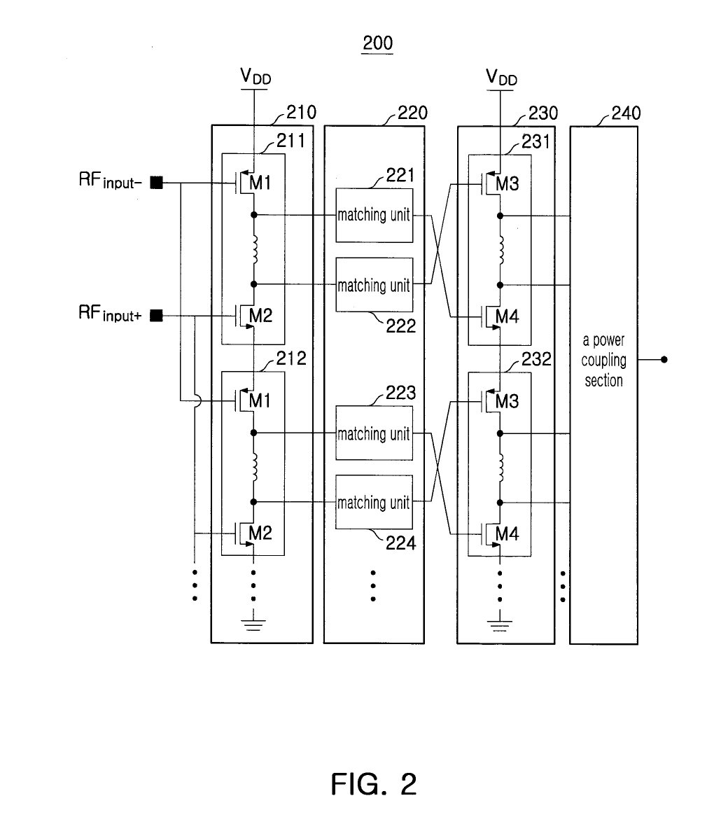

FIG. 2 is a schematic view illustrating the configuration of a power amplifier according to another exemplary embodiment of the invention.

Referring to FIG. 2, a power amplifier 200 according to this embodiment may include a first amplification section 210 and a second amplification section 230, each of which includes a plurality of amplification units, and a first matching section 220 that accordingly includes a plurality of matching units 221, 222, 223, and 224.

That is, the first amplification section 210 may include a plurality of amplification units 211 and 212 that are connected in series between the driving power terminal VDD and the ground terminal. Each of the plurality of amplification units 211 and 212 may include a first N MOS amplifier M1 and a first P MOS amplifier M2. The first N MOS amplifier M1 and the first P MOS amplifier M2 of each of the plurality of amplification units 211 and 212 may have a connected structure similar to that of the first N MOS amplifier M1 and the first P MOS amplifier M2 of the first amplification section 110 as shown in FIG. 1. However, a source of the first P MOS amplifier M2 of the first amplification unit 211 of the first amplification section 210, as shown in FIG. 2, may be connected to a source of the first N MOS amplifier M1 of the second amplification unit 212. In the same manner, a source of the first P MOS amplifier M2 of the second amplification unit 212 may be connected to the ground terminal when the first amplification section 210 includes only the first and second amplification units. In the case in which the first amplification section 210 includes other amplification units, as well as the first and second amplification units, the source of the first P MOS amplifier M2 may be connected to a source of a first N MOS amplifier M1 of an amplification unit at a rear stage.

The first matching section 220 may include a plurality of matching units 221, 222, 223, and 224. Each of the plurality of matching units 221, 222, 223, and 224 may match the impedance of a transmission path of an output signal of the first N MOS amplifier M1 or the first P MOS amplifier M2 of each of the plurality of amplification units 211 and 212 of the first amplification section 210 to a predetermined impedance. The number of matching units 221, 222, 223, and 224 of the first matching section 220 is twice as many as the number of amplification units 211 and 212 of the first amplification section 210.

In the same manner, the second amplification section 230 may include a plurality of amplification units, that is, first and second amplification units 231 and 232 that correspond to the plurality of amplification units 211 and 212 of the first amplification section 210, respectively, and are connected in series between a driving power terminal VDD and a ground terminal. Each of the plurality of amplification units 231 and 232 may include a second N MOS amplifier M3 and a second P MOS amplifier M4.

The second N MOS amplifier M3 and the second P MOS amplifier M4 of each of the plurality of amplification units 231 and 232 may have a connected structure similar to that of the second N MOS amplifier M3 and the second P MOS amplifier M4 of the second amplification section 130, as shown in FIG. 1. However, a source of the second P MOS amplifier M4 of the first amplification unit 231 of the second amplification section 230 may be connected to a source of the second N MOS amplifier M3 of the second amplification unit 232. In the same manner, a source of the second P MOS amplifier M4 of the second amplification unit 232 may be connected to the ground terminal when the second amplification section 230 includes only the first and second amplification units. In the case in which the second amplification section 230 includes other amplification units, as well as the first and the second amplification units, the source of the second P MOS amplifier M4 of the second amplification unit 232 may be connected to a source of a second N MOS amplifier M3 of an amplification unit at a rear stage.

The respective output signals of the first N MOS amplifiers M1 of the first amplification section 210 are transmitted to respective gates of the second P MOS amplifiers M4 of the second amplification section 230 corresponding thereto, while the respective output signals of the first P MOS amplifiers M2 of the first amplification section 210 are transmitted to the respective gates of the second N MOS amplifiers M3, thereby offsetting the difference in gain between the N MOS amplifiers and the P MOS amplifiers.

The power coupling section 240 may couple signals, amplified by the second N MOS amplifiers M3 and signals amplified by the second P MOS amplifiers M4 of the plurality of amplification units 231 and 232 of the second amplification section 230 to thereby output an unbalanced signal.

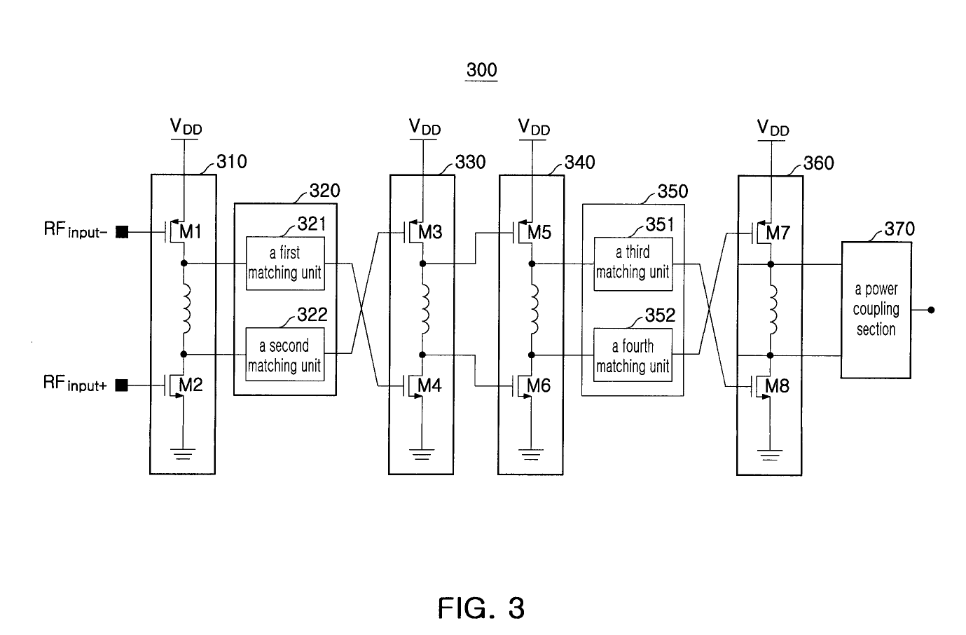

FIG. 3 is a schematic view illustrating the configuration of a power amplifier according to an exemplary embodiment of the invention.

Referring to FIG. 3, a power amplifier 300 according to this embodiment may further include a third amplification section 340, a second matching section 350, and a fourth amplification section 360 in addition to the components of the power amplifier 100 as shown in FIG. 1. Therefore, a detailed description of a first amplification section 310, a first matching section 320, and a second amplification section 330 will be omitted.

The third amplification section 340 may include at least one amplification unit. The at least one amplification unit may include a third N MOS amplifier M5 and a third P MOS amplifier M6 that are stacked between a driving power terminal VDD through which a driving power having a predetermined voltage level is supplied and a ground terminal.

The third N MOS amplifier M5 may have a source that is electrically connected to the driving power terminal VDD, a gate that receives an output signal being output through a drain of a second N MOS amplifier M3 of the second amplification section 330, and a drain that outputs an amplified signal.

In the same manner, the third P MOS amplifier M6 has a source that is electrically connected to the ground terminal, a gate that receives an output signal, being output through a drain of a second P MOS amplifier M4 of the second amplification section 230, and a drain that outputs an amplified signal. Further, the third P MOS amplifier M6 may be connected to the drain of the third N MOS amplifier M5 through an inductor. In the same manner, there may be a difference in gain between the third N MOS amplifier M5 and the third P MOS amplifier M6 due to the individual electrical characteristics thereof.

The second matching section 350 may include a first matching unit 351 and a second matching unit 352.

The first matching unit 351 matches the impedance of a transmission path of the output signal, output through the drain of the third N MOS amplifier M5, to a predetermined impedance.

In the same manner, the second matching unit 352 matches the impedance of the output signal, output through the drain of the third P MOS amplifier M6, to a predetermined impedance. Here, the first and second matching units 351 and 352 transmit the output signals to the fourth amplification section 360.

In the same manner, the fourth amplification section 360 may include at least one amplification unit. The amplification unit may include a fourth N MOS amplifier M7 and a fourth P MOS amplifier M8 that are stacked between a driving power terminal VDD supplying a driving power having a predetermined voltage level and a ground terminal.

That is, the fourth N MOS amplifier M7 may have a source that is electrically connected to the driving power terminal VDD, a gate that receives the output signal of the third P MOS amplifier M6 of the third amplification section 340, and a drain that outputs an amplified signal.

In the same manner, the fourth P MOS amplifier M8 may have a source that is electrically connected to a ground terminal, a gate that receives the output signal of the third N MOS amplifier M5 of the third amplification section 340, and a drain that outputs an amplified signal. Further, the fourth P MOS amplifier M8 may be connected to the drain of the fourth N MOS amplifier M7 through an inductor.

As described above, the output signal of the third N MOS amplifier M5 of the third amplification section 340 is transmitted to the gate of the fourth P MOS amplifier M8 of the fourth amplification section 360, while the output signal of the third P MOS amplifier M6 is transmitted to the gate of the fourth N MOS amplifier M7, thereby offsetting the difference in gain between the N MOS amplifier and the P MOS amplifier.

The power coupling section 370 may couple the signal, amplified by the fourth N MOS amplifier M7 of the fourth amplification section 360, and the signal, amplified by the fourth P MOS amplifier M8, to thereby output an unbalanced signal.

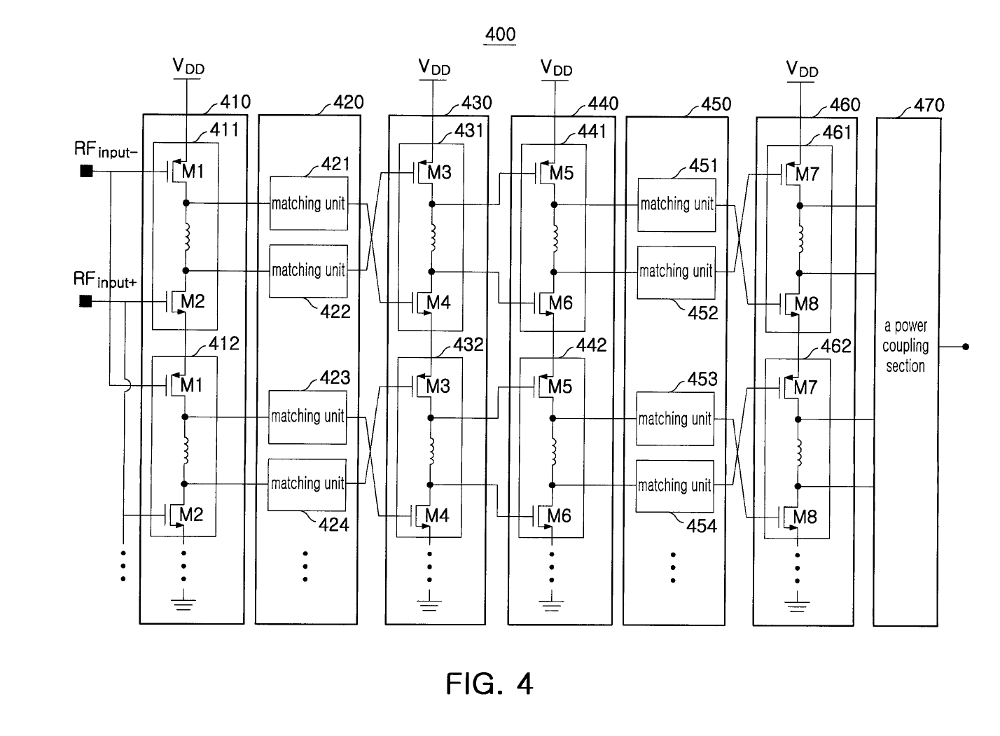

FIG. 4 is a schematic view illustrating the configuration of a power amplifier according to another exemplary embodiment of the invention.

Referring to FIG. 4, a power amplifier according to this embodiment may include first through fourth amplification sections 410, 430, 440, and 460, first and second matching sections 420 and 450, and a power coupling section 470.

The first through fourth amplification sections 410, 430, 440, and 460 may include a plurality of amplification units 411, 412, 431, 432, 441, 442, 461, and 462, respectively. Each of the plurality of amplification units 411, 412, 431, 432, 441, 442, 461, and 462 may have one of first through fourth N MOS amplifiers M1, M3, M5, and M7 and one of first through fourth P MOS amplifiers M2, M4, M6, and M8 in the same manner as the amplification units as shown in FIG. 2.

Respective output signals of the first N MOS amplifiers M1 of the plurality of amplification units 411 and 412 of the first amplification section 410 are input to respective gates of the second P MOS amplifiers M4 of the plurality of amplification units 431 and 432 of the second amplification section 430 through the matching units of the first matching section 420. Respective output signals of the first P MOS amplifiers M2 of the plurality of amplification units 411 and 412 of the first amplification section 410 are input to respective gates of the second N MOS amplifiers M3 of the plurality of amplification units 431 and 432 of the second amplification section 430 through the matching units of the first matching section 420.

Respective output signals of the second N MOS amplifiers M3 of the plurality of amplification units 431 and 432 of the second amplification section 430 are input to respective gates of the third N MOS amplifiers M5 of the plurality of amplification units 441 and 442 of the third amplification section 440, while respective output signals of the second P MOS amplifiers M4 of the plurality of amplification units 431 and 432 of the second amplification section 430 are input to respective gates of the third P MOS amplifiers M6 of the plurality of amplification units 441 and 442 of the third amplification section 440.

In the same manner, respective output signals of the third N MOS amplifiers M5 of the plurality of amplification units 441 and 442 of the third amplification section 440 are input to respective gates of the fourth P MOS amplifiers M8 of the plurality of amplification units 461 and 462 of the fourth amplification section 460 through the matching units of the second matching section 450, while respective output signals of the third P MOS amplifiers M6 of the plurality of amplification units 441 and 442 of the third amplification section 440 are input to respective gates of the fourth N MOS amplifiers M7 of the plurality of amplification units 461 and 462 of the fourth amplification section 460 through the matching units of the second matching section 450.

The power coupling section 470 may couple signals, amplified by the fourth N MOS amplifier M7 and signals, amplified by the fourth P MOS amplifier M8 of the plurality of amplification units 461 and 462 of the fourth amplification section 460 to thereby output an unbalanced signal.

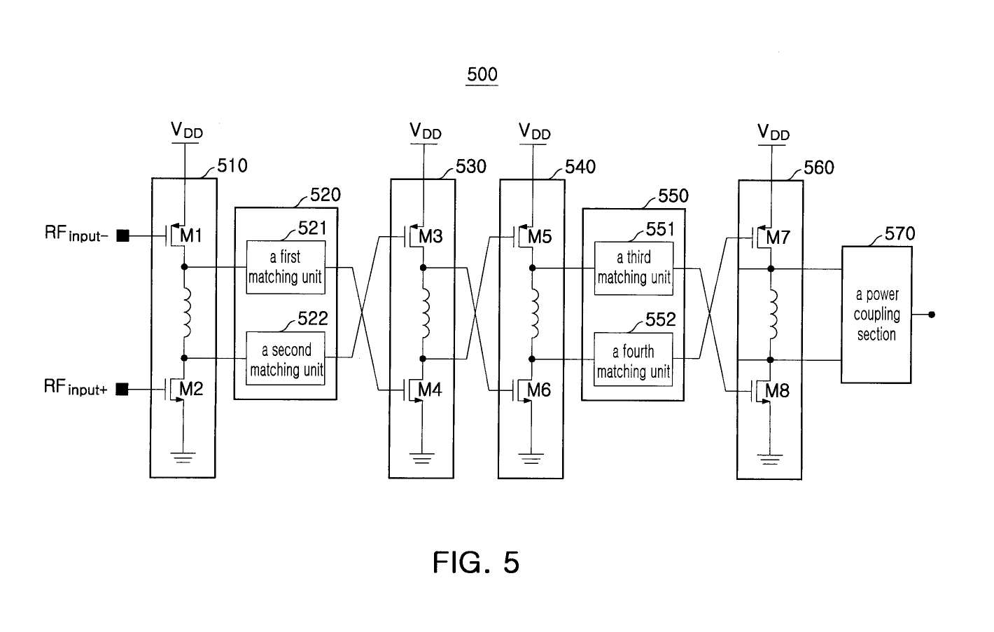

FIG. 5 is a schematic view illustrating a power amplifier according to an exemplary embodiment of the invention.

A power amplifier 500 according to this embodiment, as shown in FIG. 5, may have a configuration similar to that of the power amplifier 300 according to the embodiment as shown in FIG. 3.

However, an output signal of a second N MOS amplifier M3 of a second amplification section 530 may be input to a gate of a third P MOS amplifier M6 of a third amplification section 540, while an output signal of a second P MOS amplifier M4 of the second amplification section 530 may be input to a gate of a third N MOS amplifier M5 of the third amplification section 540.

Other components are similar to those of the power amplifier 300 according to the embodiment, as shown in FIG. 3. Thus, a detailed description of a first amplification section 510, a first amplification section 520, the second amplification section 530, a second matching section 550, a fourth amplification section 560, and a power coupling section 570 will be omitted.

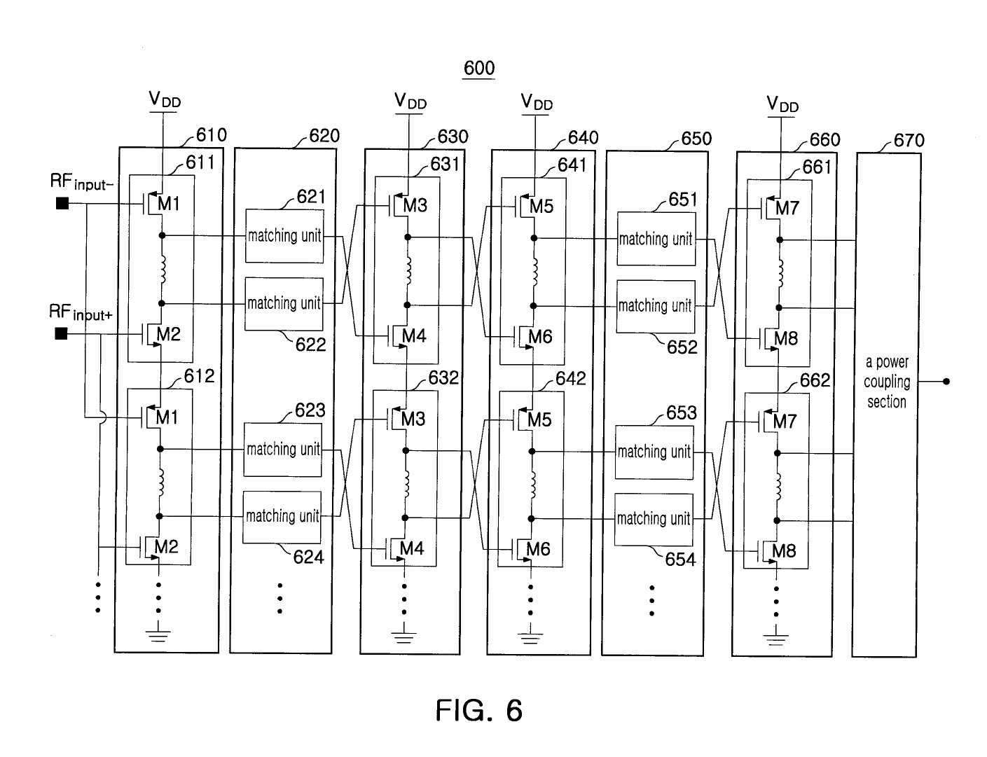

FIG. 6 is a schematic view illustrating a power amplifier according to an exemplary embodiment of the invention.

A power amplifier according to this embodiment, as shown in FIG. 6, may be configured to have a structure similar to the power amplifier according to the embodiment as shown in FIG. 4.

The power amplifier according to the embodiment, as shown in FIG. 6, may be configured to have a structure similar to that of the power amplifier as shown in FIG. 4.

However, respective output signals of second N MOS amplifiers M3 of the plurality of amplification units 631 and 632 of a second amplification section 630 may be input to respective gates of third P MOS amplifiers M6 of a plurality of amplification units 641 and 642 of a third amplification section 640, while output signals of second P MOS amplifiers M4 of plurality of amplification units 631 and 632 of a second amplification section 630 may be input to respective gates of third N MOS amplifiers M5 of the plurality of amplification units 641 and 642 of the third amplification section 640.

Other components are similar to those of the power amplifier according to the embodiment, as shown in FIG. 4. Thus, a detailed description of a first amplification section 610, a first amplification section 620, a second amplification section 630, a second matching section 650, a fourth amplification section 660, and a power coupling section 670 will be omitted.

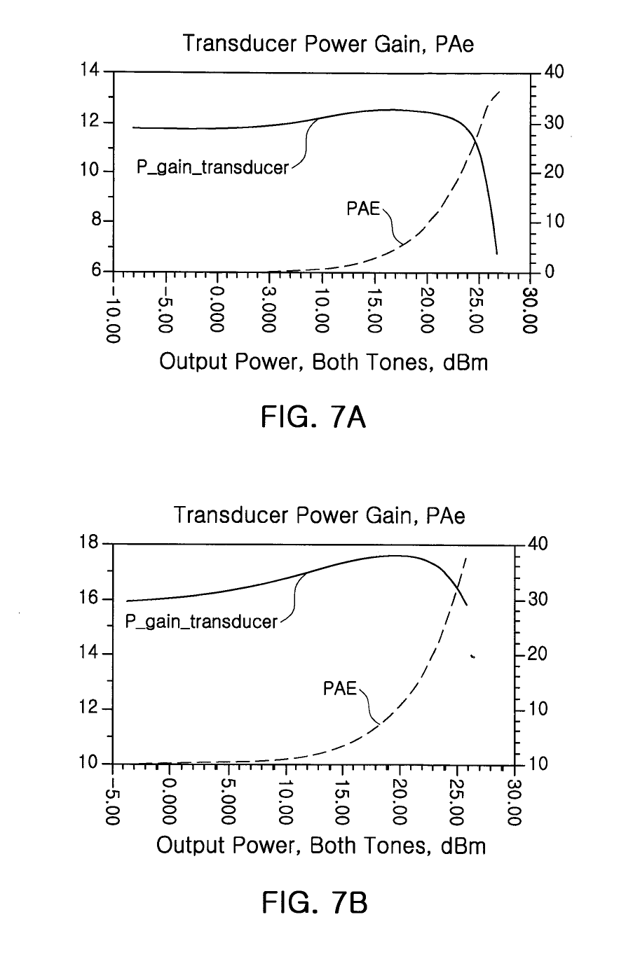

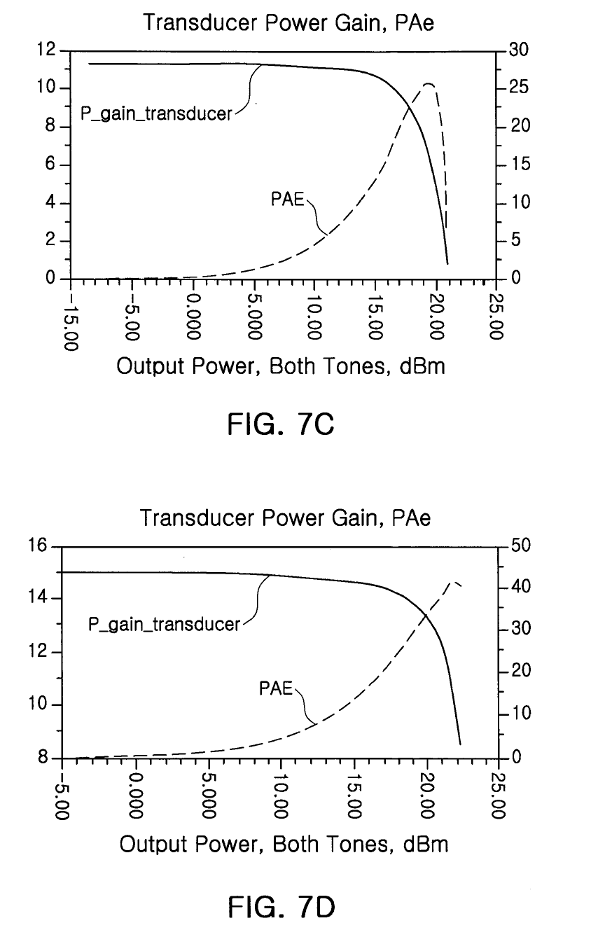

FIGS. 7A through 7D are graphs showing the electrical characteristics of an N MOS amplifier and a P MOS amplifier.

FIG. 7A is a graph showing a gain of a power stage of a P MOS amplifier, FIG. 7B is a gain of a power stage of an N MOS amplifier, FIG. 7C is a graph showing a gain of a driver stage of a P MOS amplifier, and FIG. 7D is a graph showing a gain of a driver stage of an N MOS amplifier.

As described above, as for the N MOS amplifier and the P MOS amplifier, a difference in gain is shown to exist between the power stage and the driver stage despite the use of the same DC current.

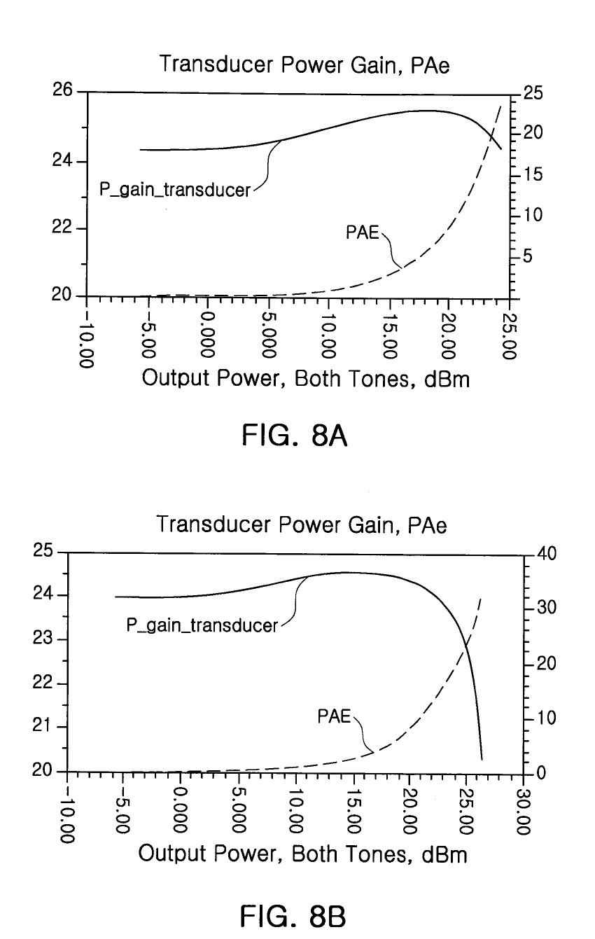

FIGS. 8A and 8B are graphs illustrating the electrical characteristics of a power amplifier according to an exemplary embodiment of the invention.

FIG. 8A is a graph showing a gain of a path connecting a driver stage of a P MOS amplifier and a power stage of an N MOS amplifier. FIG. 8B is a graph showing a path connecting a driver stage of an N MOS amplifier and a power stage of a P MOS amplifier.

When compared to FIGS. 7A and 7B, little difference in gain is shown between the paths, as shown in FIGS. 8A and 8B.

As set forth above, according to exemplary embodiments of the invention, according to an exemplary embodiment of the invention, in a power amplifier having amplification units with a stacked structure in which N MOS amplifiers and P MOS amplifiers are connected in series with each other, outputs from a two-stage amplification unit are cross-connected to each other, thereby reducing a gain mismatch between the N MOS amplifiers and the P MOS amplifiers.

While the present invention has been shown and described in connection with the exemplary embodiments, it will be apparent to those skilled in the art that modifications and variations can be made without departing from the spirit and scope of the invention as defined by the appended claims.

What is claimed is:

1. A power amplifier reducing a gain mismatch, the power amplifier comprising:
a first amplification section including at least one first amplification unit having a first N MOS amplifier and a first P MOS amplifier stacked between a driving power terminal, through which a driving power having a predetermined voltage level is supplied, and a ground terminal;
a first matching section performing impedance matching of respective output signals of the first N MOS amplifier and the first P MOS amplifier of the first amplification section;
a second amplification section including at least one second amplification unit having a second N MOS amplifier and a second P MOS amplifier stacked between the driving power terminal and the ground terminal, inputting the output signal of the first N MOS amplifier of the first amplification section to the second P MOS amplifier and the output signal of the first P MOS amplifier of the first amplification section; and
a power coupling section coupling output signals of the second N MOS amplifier and the second P MOS amplifier of the second amplification section.

2. The power amplifier of claim 1, wherein the first N MOS amplifier has a source connected to the driving power terminal, a gate receiving a negative input signal among balanced input signals being input, and a drain outputting an amplified signal, and
the first P MOS amplifier has a source connected to the ground terminal, a gate receiving a positive input signal among the balanced input signals being input, and a drain outputting an amplified signal and connected to the first N MOS amplifier through an inductor.

3. The power amplifier of claim 2, wherein the first matching section comprises:
a first matching unit matching an impedance of a transmission path of the output signal through the drain of the first. N MOS amplifier to a predetermined impedance and transmitting the output signal to the gate of the second P MOS amplifier of the second amplification section; and
a second matching unit matching an impedance of a transmission path of the output signal through the drain of the first P MOS amplifier and transmitting the output signal to the gate of the second N MOS amplifier of the second amplification section.

4. The power amplifier of claim 3, wherein the second N MOS amplifier has a source connected to the driving power terminal, a gate receiving the output signal of the first P MOS amplifier from the second matching unit, and a drain outputting an amplified signal, and
the second P MOS amplifier has a source connected to the ground terminal, a gate receiving the output signal of the first N MOS amplifier from the first matching unit, and a drain outputting an amplified signal and connected to the drain of the second N MOS amplifier through an inductor.

5. The power amplifier of claim 1, wherein the first amplification section comprises a plurality of first amplification units,
each of the plurality of first amplification units has a first N MOS amplifier and a first P MOS amplifier stacked,
the first N MOS amplifier has a gate receiving a negative input signal among balanced input signals being input and a drain outputting an amplified signal,
the first P MOS amplifier has a gate receiving a positive input signal among the balanced input signals being input and a drain outputting an amplified signal and electrically connected to the drain of the first N MOS amplifier through an inductor, and
the plurality of first amplification units are connected in series between the driving power terminal and the ground terminal.

6. The power amplifier of claim 5, wherein the first matching section comprises a plurality of matching units matching impedances of transmission paths of respective output signals being output through drains of the first N MOS amplifier and the first P MOS amplifier of each of the plurality of first amplification units.

7. The power amplifier of claim 6, wherein the second amplification section comprises a plurality of second amplification units respectively corresponding to the plurality of first amplification units of the first amplification section,
each of the plurality of second amplification units comprises a second N MOS amplifier and a second P MOS amplifier stacked,
the second N MOS amplifier has a gate receiving an output signal of a first P MOS amplifier of a corresponding first amplification unit among the plurality of first amplification units from one of the plurality of matching units, and a drain outputting an amplified signal,
the second P MOS amplifier has a gate receiving an output signal of a first N MOS amplifier of a corresponding first amplification unit among the plurality of first amplification units from one of the plurality of matching units, and a drain outputting an amplified signal and electrically connected to the drain of the second N MOS amplifier through an inductor,
the plurality of second amplification units are connected in series between the driving power terminal and the ground terminal, and
the power coupling section couples the output signals of the second N MOS amplifier and the second P MOS amplifier of each of the plurality of second amplification units.

8. The power amplifier of claim 4, further comprising, between the second amplification section and the power coupling section:
a third amplification section including at least one third amplification unit having a third N MOS amplifier and a third P MOS amplifier stacked between the driving power terminal and the ground terminal, and amplifying the output signals of the second amplification section;
a second amplification section performing impedance matching of respective output signals from the third N MOS amplifier and the third P MOS amplifier of the third amplification section; and
a fourth amplification section including at least one fourth amplification unit having a fourth N MOS amplifier and a fourth P MOS amplifier stacked between the driving power terminal and the ground terminal, inputting the output signal of the third N MOS amplifier of the third amplification section to the fourth P MOS amplifier, and inputting the output signal of the third P MOS amplifier of the third amplification section to the second N MOS amplifier, and
the power coupling section couples output signals of the fourth N MOS amplifier and fourth P MOS amplifier of the fourth amplification section.

9. The power amplifier of claim 8, wherein the third N MOS amplifier has a source connected to the driving power terminal, a gate receiving the output signal of the second N MOS amplifier, and a drain outputting an amplified signal,
the third P MOS amplifier has a source connected to the ground terminal, a gate receiving the output signal of the second P MOS amplifier, and a drain outputting an output signal being amplified and connected to the drain of the third N MOS amplifier,
the second amplification section comprises a third matching unit matching an impedance of a transmission path of the output signal through the drain of the third N MOS amplifier to a predetermined impedance and transmitting the output signal to the gate of the fourth P MOS amplifier of the fourth amplification section, and a fourth matching unit matching an impedance of a transmission path of the output signal through the drain of the third P MOS amplifier to a predetermined impedance and transmitting the output signal to the gate of the fourth N MOS amplifier of the fourth amplification section,
the fourth N MOS amplifier has a source connected to the driving power terminal, a gate receiving the output signal of the third P MOS amplifier from the fourth matching unit, and a drain outputting an output signal being amplified, and
the fourth P MOS amplifier has a source connected to the ground terminal, a gate receiving the output signal of the third N MOS amplifier of the third matching unit, a drain outputting an output signal being amplified and connected to the drain of the fourth N MOS amplifier through an inductor.

10. The power amplifier of claim 9, wherein the third N MOS amplifier has a source connected to the driving power terminal, a gate receiving the output signal, of the second P MOS amplifier, and a drain outputting an amplified signal,
the third P MOS amplifier has a source connected to the ground terminal, a gate receiving the output signal of the second N MOS amplifier, and a drain outputting an output signal being amplified and connected to the drain of the third N MOS amplifier through an inductor,
the second amplification section comprises a third matching unit matching an impedance of a transmission path of the output signal through the drain of the third N MOS amplifier to a predetermined impedance and transmitting the output signal to the gate of the fourth P MOS amplifier of the fourth amplification section, and a fourth matching unit matching an impedance of a transmission path of the output signal through the drain of the third P MOS amplifier to a predetermined impedance and transmitting the output signal to the gate of the fourth N MOS amplifier of the fourth amplification section,
the fourth N MOS amplifier has a source connected to the driving power terminal, a gate receiving the output signal of the third P MOS amplifier from the fourth matching unit, and a drain outputting an output signal being amplified, and
the fourth P MOS amplifier has a source connected to the ground terminal, a gate receiving the output signal of the third N MOS amplifier of the third matching unit, a drain outputting an output signal being amplified and connected to the drain of the fourth N MOS amplifier through an inductor.

11. The power amplifier of claim 7, further comprising, between the second amplification section and the power coupling section,
a third amplification section having a plurality of third amplification units respectively corresponding to the plurality of second amplification units of the second amplification section, the plurality of third amplification units each having a third N MOS amplifier and a third P MOS amplifier being stacked, the third N MOS amplifier having a gate receiving an output signal of a second P MOS amplifier of a corresponding second amplification unit among the plurality of second amplification units, and a drain outputting an amplified signal, the third P MOS amplifier having a gate receiving an output signal of a second N MOS amplifier of a corresponding second amplification unit among the plurality of second amplification units, and a drain amplifying an amplified signal and electrically connected to the drain of the third N MOS amplifier through an inductor, and the plurality of third amplification units connected in series between the driving power terminal and the ground terminal;
a second matching section having a plurality of matching units matching impedances of transmission paths of respective output signals being output through the drain of the third N MOS amplifier and the drain of the third P MOS amplifier of each of the plurality of third amplification units; and
a fourth amplification section having a plurality of fourth amplification units respectively corresponding to the plurality of third amplification units of the third amplification section, the plurality of fourth amplification units each having a fourth N MOS amplifier and a fourth P MOS amplifier being stacked, the fourth N MOS amplifier having a gate receiving an output signal of a third P MOS amplifier of a corresponding third amplification unit among the plurality of third amplification units from one matching unit of the plurality of matching units of the second matching section, and a drain outputting an amplified signal, the fourth P MOS amplifier having a gate receiving an output signal of a third N MOS amplifier of a corresponding third amplification unit among the plurality of third amplification units from one matching unit of the plurality of matching units of the second matching section, and a drain outputting an amplified signal and connected to the drain of the fourth N MOS amplifier through an inductor, and the plurality of fourth amplification units connected in series between the driving power terminal and the ground terminal, and
the power coupling section couples the output signals of the fourth N MOS amplifier and the fourth P MOS amplifier of each of the plurality of fourth amplification units.

12. The power amplifier of claim 7, further comprising, between the second amplification section and the power coupling section:
a third amplification section having a plurality of third amplification units respectively corresponding to the plurality of second amplification units of the second amplification section, the plurality of third amplification units each having a third N MOS amplifier and a third P MOS amplifier being stacked, the third N MOS amplifier having a gate receiving an output signal of a second N MOS amplifier of a corresponding second amplification unit among the plurality of second amplification units, and a drain outputting an amplified signal, the third P MOS amplifier having a gate receiving an output signal of a second P MOS amplifier of a corresponding second amplification unit among the plurality of second amplification units, and a drain amplifying an amplified signal and electrically connected to the drain of the third N MOS amplifier through an inductor, and the plurality of third amplification units connected in series between the driving power terminal and the ground terminal;
a second matching section having a plurality of matching units matching impedances of transmission paths of respective output signals being output through the drain of the third N MOS amplifier and the drain of the third P MOS amplifier of each of the plurality of third amplification units; and
a fourth amplification section having a plurality of fourth amplification units respectively corresponding to the plurality of third amplification units of the third amplification section, the plurality of fourth amplification units each having a fourth N MOS amplifier and a fourth P MOS amplifier being stacked, the fourth N MOS amplifier having a gate receiving an output signal of a third P MOS amplifier of a corresponding third amplification unit among the plurality of third amplification units from one matching unit of the plurality of matching units of the second matching section, and a drain outputting an amplified signal, the fourth P MOS amplifier having a gate receiving an output signal of a third N MOS amplifier of a corresponding third amplification unit among the plurality of third amplification units from one matching unit of the plurality of matching units of the second matching section, and a drain outputting an amplified signal and connected to the drain of the fourth N MOS amplifier through an inductor, and the plurality of fourth amplification units connected in series between the driving power terminal and the ground terminal, and
the power coupling section couples the output signals of the fourth N MOS amplifier and the fourth P MOS amplifier of each of the plurality of fourth amplification units.
